(19) United States
(12) Patent Application Publication
(10) Pub. No.: US 2011/0214717 A1
(43) Pub. Date: Sep. 8, 2011

(54) LIGHT CURABLE PHOTOVOLTAIC CELL ENCAPSULANT

(75) Inventors: Izhar Halahmi, Hod Hasharon (IL); Pasha Solel, Tel Aviv (IL); Itay Baruchi, Tel Aviv (IL)

(73) Assignee: PYTHAGORAS SOLAR INC., Wilmington, DE (US)

(21) Appl. No.: 13/128,680

(22) PCT Filed: Nov. 12, 2009
(86) PCT No.: PCT/IL09/01064

§ 371 Date: May 11, 2011

Related U.S. Application Data
(60) Provisional application No. 61/193,260, filed on Nov. 12, 2008.

(51) Int. Cl. H01L 31/048; C08L 75/16; C08L 33/04; C08J 3/28

(52) U.S. Cl. 136/251; 522/96; 522/120; 522/42; 522/44; 522/33; 522/64

(57) ABSTRACT

Provided are photovoltaic modules that can include a liquid encapsulant formulation. Also provided are such liquid encapsulant formulations.

### FIELD OF THE INVENTION

This invention relates to a light curable liquid encapsulant for use in the construction of photovoltaic cells and modules.

### BACKGROUND OF THE INVENTION

Photovoltaic (PV) cells convert sunlight directly into electrical energy. The electricity produced may be used as direct current, converted to alternating current through the use of an inverter, or stored for later use in a battery. In its simplest form, a photovoltaic device is a solar-powered battery which only consumable is light. Because sunlight is unlimitedly available, photovoltaics have many advantages over traditional power sources.

Although photovoltaic cells come in a variety of forms, the most common structure is a semiconductor material into which a large-area diode, or p-n junction, has been formed. In terms of basic function, electrical current is taken from the device through a contact structure typically on the front that allows the sunlight to enter the solar cell and a contact on the back that completes the circuit.

A photovoltaic module consists of several photovoltaic cells, electrically connected to one another. The cells are sandwiched between a transparent protective material, typically glass on one side, and a barrier layer, usually a metal or a metallized polymer sheet, on the back. Typical photovoltaic modules utilize a polymeric layer to encapsulate, seal and protect the PV module and PV cells. The most typical encapsulant materials (herein referred to as encapsulants) are thermoplastics that are laminated under pressure and heat, usually between the PV cell and the protective layers which are typically glass. Most encapsulants, especially vinyl acetate, are cross-linked during the lamination stage. The disadvantages of thermoplastic encapsulants, such as ethylene vinyl acetate (EVA), polyvinyl butyral (PVB) and ionomer resins are the need for high pressures and temperatures during lamination, their tendency to leave voids, tendency to yellow during exposure to UV light and heat (during service outdoor), need for long curing (cross-linking) periods (negative economical aspect), high modulus of elasticity places a risk on the durability of thin PV cells during service—especially under thermal cycling, and their poor adhesion to materials other than that of the PV cell and glass (polymeric films and sub-assemblies).

Alternatively, addition curing silicones are used as encapsulants. In contrast to the use of thermoplastics, the advantages of using silicones include their high stability against yellowing and discoloration, low modulus of elasticity, low Tg (retaining their elasticity at temperatures lower than −20° C. and even lower than −45° C.) and wide service temperature latitude. The disadvantages are poor adhesion to plastic materials, low strength, high risk of inhibition during curing (an inhibition which may be caused by residues of soldering flux, residues of other adhesives such as epoxy, contact by latex gloves and sulfur cured gaskets and o-rings) and long curing time. Additionally, since most solar silicone encapsulants, comprise high percentage of monomeric silane adhesion promoters, they tend to haze during damp/heat aging. Another drawback of silicone encapsulants is their relative price—about 2 to 5 times more expensive than thermoplastic encapsulants.

Attempts to provide polyacrylic acid ester as encapsulants have been met with some success. U.S. Pat. No. 4,383,129 discloses an encapsulant made of polybutyl acrylate dissolved in butyl acrylate as “syrup” that is provided as liquid encapsulant in the PV module and cured afterwards. The process involves curing of the mixture by thermally activated free radical source, which is by itself a slow process. Another disadvantage has to do with the relatively poor physical properties of polybutyl acrylate due to lack of cross-linking and the poor adhesion to glass and silicone module, due to lack of polar groups (for example carboxyl, anhydride, organo metallic, and hydroxyl). Additionally, as photovoltaic modules become thinner, the need for very soft encapsulant is increasing. Polybutylacrylate is not soft enough.

### REFERENCES

[1] U.S. Pat. No. 4,383,129

### SUMMARY OF THE INVENTION

The inventors of the present invention have now developed an encapsulant formulation for encapsulating a PV cell and for bonding thereof to adjacent material surfaces such as glass and plastics, for the construction of PV modules comprising one or more such cells, as disclosed herein. The invention particularly provides an encapsulant characterized by low viscosity at the molding temperature, usually between 20° and 80° C., good adhesion to, e.g., glass and the PV module, as well as to polymeric films and sheets, having a low Tg retaining its elasticity below −20° C., low modulus of elasticity at a temperature range from +90° C. to −45° C., high durability against yellowing under UV light and heat (the conditions typical to PV module installed outdoors) and cures to high molecular and/or partially cross-linked soft plastic or elastomeric mass within seconds or minutes when exposed to light.

Additionally, the encapsulant of the invention is designed to have a dispersion profile (its refraction index as a function of wavelength) matching that of the PV cell material in the spectral range, so as high electrical efficiency is obtained.

Thus, the invention provides, in one of its aspects, an encapsulant formulation, (e.g., for encapsulating a photovoltaic cell and for bonding same to at least one surface material) comprising at least one high durability polymer (HDP), at least one unsaturated monomer and/or oligomer, and at least one photoinitiator. It should be noted that the definition and characteristics of the encapsulant formulation provided herein, unless otherwise specifically noted, relates to an uncured liquid formulation.

In some embodiments, when the formulation is cured, it is characterized by durability to outdoor weathering, good adhesion to glass and the PV cell, e.g., silicone, thin film, multijunction cells, low elastic modulus (especially at temperatures as low as −45° C.), low glass transition temperature and transparency over 85-90% (at a wavelength of 300-800 nanometer, at a film thickness of 0.5 mm).

The encapsulant formulation of the invention, being a liquid at room temperature or at the application temperature, e.g., typically between room temperature and 100° C., has a viscosity, at the temperature of application, in the range of 5 to 50,000 centipoises (cps) at shear rate of 10 sec⁻¹. In some embodiments, the formulation has a viscosity of lower than 25,000 cps at 25° C. at shear rate of 10 sec⁻¹. In additional embodiments, the formulation has viscosity of lower than 10,000 cps at 25° C. at shear rate of 10 sec⁻¹, and in still further embodiments, the formulation has a viscosity of lower than 5,000 cps at 25° C. at shear rate of 10 sec⁻¹.

The at least one HDP polymer employed in the formulation of the invention is a resilient and elastic polymer selected to retain at least one of its mechanical and/or optical properties over time, e.g., when exposed outdoors to sunlight (e.g., UV, visible and/or IR radiation) and heat. The HDP is a linear or branched aliphatic or cycloaliphatic polymer selected from (a) polyester including polyester acrylates and methacrylates, (b) polyurethane including polyurethane acrylates, and (c) acrylic polymers. The acrylic polymers employed are typically selected amongst homopolymers, copolymers and terpolymers, linear, segmented, alternate, branched, block and cyclic, wherein at least 50% of the polymer repeating units are selected from acrylic or methacrylic acid, ester or amide or urethane ester or amide.

In some embodiments, the HDP is prepared from acrylic and/or methacrylic acid, esters, amide or urethane in the form of a polymer or an oligomer. The HDP may comprise one or more of same or different repeating units (e.g., one or more different acrylic or methacrylic acid and derivatives thereof).

In some embodiments, the HDP comprises a single type of monomers (homopolymer) and in other embodiments it comprises a mixture of two or more such monomers (copolymer and terpolymers). The copolymer employed may be random, block, branched, grafted or alternate. The HDP may be prepared by copolymerization of one or more acrylic or methacrylic esters, urethanes or amides in a bulk, solution, an emulsion, a dispersion using radical, anionic or cationic initiator.

In some embodiments, the at least one monomer is selected amongst alkyl acrylates or methacrylates.

The at least one HDP has a Tg (as measured by a method selected from differential scanning calorimetry (DSC), Thermo mechanical analysis (TMA) and dynamic mechanical analysis (DMA)) lower than 50° C. In some embodiments, the Tg is lower than 40° C.

In some embodiments, the Tg is lower than 0° C. In further embodiments, the Tg is lower than −20° C. In other embodiments, the Tg is lower than −40° C.

Non-limiting examples of such polymers are NanoStrength acrylic copolymers (manufactured by Arkema), Elvacite (manufactured by Lucite) and Joncryl (manufactured by BASF).

In some embodiments, said at least one HDP is a block copolymer, wherein the Tg is the lower of the at least two Tg values of the copolymer blocks.

In other embodiments, the at least one HDP is an acrylic or methacrylic ester or amide or urethane, homopolymer, copolymer including random, alternate, block copolymer, and terpolymer including random, alternate and block terpolymers. Non-limiting examples of such acrylic or methacrylic acid esters, amides, urethanes or ethers are butyl acrylate, octyl acrylate, decyl acrylate, iso-decyl acrylate, tridecyl acrylate, ethyl hexyl acrylate, ethoxylated ethyl hexyl acrylate, octyl decyl acrylate, di-ethylene glycol 2-ethylhexyl ether acrylate, tetra decyl acrylate, cetyl acrylate, stearyl acrylate, behenyl acrylate, polyethylene glycol mono acrylate, acrylamide, urethane acrylate, urethane methacrylate and caprolactone acrylate. Also encompassed are the methacrylate equivalents of each of the exemplified acrylate compounds.

As used herein, the terms “copolymer” and “terpolymer” are as defined in the art, and independently of each other, refer to one or more types of monomers copolymerized to any degree and selected in a non limiting manner from random, block, alternate and graft copolymers and terpolymers.

Without wishing to be bound by theory, the at least one HDP utilized in the formulation of the invention provides the cured encapsulant formulation with resilience, strength, low shrinkage during curing, high transparency and low haze, high peel adhesion strength, high tear strength and controlled viscosity of the liquid state, and also affects the rate of curing of the unsaturated monomer or oligomer, due to the increased viscosity. The additional benefit of using the HDP polymers disclosed herein resides in the ability to increase the concentration of said polymer in the formulation to thereby reduce the content of relatively toxic and irritating monomers and oligomers which have been traditionally used in such formulations.

In some embodiments, the concentration of the at least one HDP in the formulation is at least 10% of the total weight of the formulation. In other embodiments, the concentration of the at least one HDP in the formulation is between 10 and 90% of the total weight of the formulation. In other embodiments, the concentration of the at least one HDP in the formulation is between is 15 and 75% of the total weight of the formulation. In still further embodiments, the concentration of the at least one HDP in the formulation is between 20 and 65% of the total weight of the formulation.

The at least one monomer or oligomer employed in the formulation of the invention is selected to provide the liquid encapsulant mixture with low viscosity, good wetting of a substrate, and/or ease of application at moderate pressures and/or temperatures, and further provide the encapsulant in the cured state with a low Tg, adhesion to substrate, controlled degree of cross-linking and high transparency.

The at least one unsaturated monomer or oligomer is an aliphatic, heterocyclic or cycloaliphatic monomer or an oligomer (having a molecular weight greater than 200 Daltons and/or a viscosity of lower than 10,000 cps at 25° C.) characterized by a viscosity at 25° C. of 5 to 10,000 cps. The unsaturated monomer or oligomer is selected so as to be resistant to UV- and/or heat-induced degradation, namely the unsaturated monomer or oligomer does not undergo degradation under such conditions, be it short term or long term. Each of said at least one unsaturated monomer or oligomer has at least one reactive group per molecule, said reactive group being selected from acryl, methacryl, fumaryl, vinyl, allyl and unsaturated polyester.

In some further embodiments, said at least one unsaturated monomer or oligomer is selected amongst aliphatic, cycloaliphatic and heterocyclic monomers and oligomers, having each at least one side group being different from aryl and conjugated double bonds; said monomer or oligomer being characterized by (1) a low adsorption of UV light (2) high stability against oxidation.

Non-limiting examples of the at least one unsaturated monomer are medium or long chain alkyl acrylate or methacrylate esters such as lauryl acrylate or methacrylate (the term acrylate refer hereinafter to both acrylic acid and methacrylic acid derivatives), glycol and poly glycol acrylate, silicone acrylate, butyl acrylate, octyl acrylate, decyl acrylate, iso-decyl acrylate, tridecyl acrylate, ethyl hexyl acrylate, ethoxylated ethyl hexyl acrylate, octyl decyl acrylate, di ethylene glycol 2-ethylhexyl ether acrylate, 2-(2-ethoxyethoxy)ethyl acrylate (EOEOEA), tetrahydro furfuryl acrylate, tetradecyl acrylate, cetyl acrylate, stearyl acrylate, behenyl acrylate, polyethylene glycol mono acrylate and caprolactone acrylate, 2-ethylhexyl acrylate, urethane acrylate, polyethylene glycol acrylate and any methacrylate derivative equivalent of any of the listed acrylates.

Non-limiting examples of the at least one unsaturated oligomer are a urethane acrylate, a polyester acrylate and an aliphatic unsaturated polyester or any methacrylate derivative thereof.

In some embodiments, the concentration of said at least one monomer or oligomer in the formulation of the invention is at least 10% of the total weight of the formulation. In further embodiments, the concentration of said at least one monomer or oligomer in the formulation of the invention is between 10 and 90% of the total weight of the formulation. In still further embodiments, the concentration of said at least one monomer or oligomer in the formulation of the invention is between 20 and 80% of the total weight of the formulation. In other embodiments, the concentration of the at least one monomer or oligomer is between 30 and 70% of the total weight of the formulation.

Additionally, in some embodiments, the encapsulant formulation of the invention comprises a mixture of at least one monomer and at least one oligomer, as defined. In other embodiments, the encapsulant comprises at least one monomer or at least one oligomer.

As used herein, the at least one monomer or at least one oligomer may be in the form of a mixture of different monomers or different oligomers, respectively. Mixtures of monomers and oligomers may comprise two or more different monomers with one or more different oligomers, two or more different oligomers with one or more different monomers, two or more different monomers with two or more different oligomers or any other combination thereof.

The encapsulant formulation according to the present invention may also comprise at least one plasticizer, said plasticizer being selected so as to enable modification of the hardness of the encapsulant and optionally also provide modification of Tg (in order to lower Tg, so that the encapsulant retains its elasticity and low modulus of elasticity at temperatures as low as −50° C.), so as to obtain a soft elastomer, with minimized applied stresses on the PV module during thermal cycles.

The at least one plasticizer employed in the encapsulant formulation of the invention is selected amongst an aliphatic ester of a long alkyl alcohol, an ester of an aliphatic acid including di acids and poly acids and an ester of a polyethylene or a polypropylene glycol.

Non-limiting examples of such plasticizers are adipic acid mono and di-ester, azelaic acid mono and di-ester, glutaric acid mono and di-ester, maleic acid mono and di-ester, and sebacic acid mono and di-ester.

The amount of plasticizer employed in the formulation of the invention is limited to the haze point, namely to the loading point where the transparency of the cured encapsulant deteriorates and haze is observed. In some embodiments, the concentration of the at least one plasticizer in the formulation of the invention is between 0 and 50% or 60% or 70% of the total weight of the formulation. In other embodiments, the concentration of said at least one plasticizer is between 0 and 20% or 30% or 40% of the total weight of the formulation. In still other embodiments, the concentration of said at least one plasticizer is between 0 and 10% or 20% or 30% of the total weight of the concentration.

The encapsulant formulation of the invention comprises also at least one photoinitiator which initiates polymerization and cross-linking (under UV and/or visible light) of the unsaturated monomer or oligomer and optionally at least one adhesion promoting monomer or oligomer to form a dimensionally stable, soft and elastic encapsulant mass.

Non-limiting examples of said at least one photoinitiator include 2-hydroxy-2-methyl-1-phenyl-propan-1-one, 2,4,6-trimethylbenzoyl-diphenyl-phosphineoxide, 1-hydroxy-cyclohexyl-phenyl-ketone, bis(2,6-dimethoxybenzoyl)-2,4,4-trimethyl-pentyl phosphine oxide, 1-[4-(2-hydroxyethoxy)-phenyl]-2-hydroxy-2-methyl-1-propane-1-one, 2,2-dimethoxy-1,2-diphenylethan-1-one and 2-methyl-1[4-(methylthio)phenyl]-2-morpholinopropan-1-one.

In some embodiments, said at least one photoinitiator is selected to have a light activation in the visible spectrum, so that curing can be achieved when the light is provided through glass or other UV screening protective layers. Examples for such photoinitiators are phenylphosphineoxides such as Irgacure 819 manufactured by Ciba and Lucirin TPO manufactured by BASF.

The concentration of said at least one photoinitiator is between 0.05% and 10% of the total weight of the formulation.

The encapsulant formulation of the invention may also comprise at least one adhesion promoting agent in the form of a monomer, an oligomer or a polymer, which is capable of interacting with the surfaces. For example, acidic monomers, polymers and oligomers, interact with surfaces such as metal oxide surfaces, e.g., aluminum, via acid-base interactions; organo metallic adhesion promoters form covalent or coordinative bonds with metals and oxides thereof, including silicone and oxide thereof (e.g., glass), etc.

The at least one adhesive promoting agent is selected from (1) a monomer, an oligomer and/or a polymer having at least one polar group, such as a carboxyl, an anhydride, an hydroxyl and a phosphate group; and (2) an organo metallic compound, such as an organo-silicon compound, an organo-titanium compound and an organo-zirconium compound.

Non-limiting examples of such adhesion promoting monomers or oligomers having at least one polar group are acrylic acid, an acidic oligomers such as SR 9050 manufactured by Sartomer, bis(2-methacryloxyethyl) phosphate, ADDITOL® XL 185 manufactured by Cytec, Lubrizol 2061 and Lubrizol 2063 manufactured by Lubrizol and maleic anhydride.

Non-limiting examples of organo metallic compounds are organo silanes such as Z-6030 and Z-6300 manufactured by Dow corning, organo titanates such as Tyzor manufactured by Du-Pont and Ken-React manufactured by Kenrich petrochemicals and organo zirconates such as Ken-React manufactured by Kenrich petrochemicals.

In some embodiments, the concentration of said at least one adhesion promoting monomer or oligomer having at least one polar group is between about 0 and 25% of the total weight of the formulation. In other embodiments, the concentration of adhesive promoting organo metallic monomer or oligomer is between about 0 and 10% of the total weight of the formulation.

The formulation of the invention optionally comprises at least one stabilizer, being selected so as to lower the coloration, yellowness and loss of elasticity of the encapsulant due to UV light, sun light and thermal induced degradation, e.g., oxidative degradation. The at least one stabilizer is typically an antioxidant selected from phenolic antioxidants, phosphite antioxidants, thioester antioxidants and hindered amine light stabilizers (herein referred to as HALS). In some embodiments, the formulation is free of antioxidants.

In some embodiments, the concentration of the at least one stabilizer in the formulation of the invention is between 0% and 5% of the total weight of the formulation.

As stated hereinabove, the encapsulant formulation is a liquid at room temperature or at the molding or pouring temperature that may be above room temperature.

The encapsulant formulation may be prepared by first forming two separate bulk formulations, in the form of an adhesive Part A and Part B, which may combined to the encapsulant formulation at a desired point in time, prior to application. Alternatively, the encapsulant may be prepared by mixing the ingredients into one formulation to thereby obtain the ready-for-use encapsulate. As may be understood, while both formulation forms are within the scope of the present invention, each form has inherent advantages and disadvantages which are associated therewith. For example, the advantage of the one component encapsulant is the ease of application while its disadvantage is its shortened shelf life.

A two-component encapsulant enables incorporation of a secondary cross-linking mechanism in parallel to the photo-curing, for example via the reaction of polyols with isocyanates, the reaction of siloxanes with humidity, the reaction of epoxy with amine or anhydride and the reaction of vinyl terminated silicone polymer with silane hydride terminated polymer.

Both Parts A and B may be stored separately or mixed into a single formulation having viscosity stability (shelf life) over a long period of time.

The encapsulant formulation thus prepared may be applied to encapsulate a PV module, by any means known in the art. In some embodiments, the encapsulant formulation is dispensed onto the open PV module and thereafter assembled, without applying any significant pressure or force.

In some other embodiments, the formulation is applied by pumping the encapsulant onto the PV surface or into a pre-made cavity to be filled. The pressure required to pump the liquid into the cavity is usually in the range of zero (free pouring) to about 1 atmosphere gauge. In some embodiments, the pressure is 0.5 atmosphere gauge. In other embodiments the pressure is between 0.1 and 0.4 atmosphere gauge.

In other embodiments, the formulation is applied by pouring.

After application, curing of the encapsulant formulation is enabled by means of UV and/or visible light, heat, IR irradiation or combinations thereof. Such curing provides a cured encapsulant layer thickness ranging from 10 microns to 10 millimeters or from 10 microns to 5 millimeters. The curing is typically achieved through an outer protective layer, selected from glass or a polymeric film. Typically, the liquid formulations (in the uncured state) of the invention are cured (cross-linked and polymerized) to at least 90% conversion (measured by percentage of unsaturated groups consumed) within 1 to 1,000 seconds.

In some embodiments, curing (e.g., to at least 90% conversion) is achieved by employing a UV and/or visible light source selected from a mercury lamp, a plasma ignited lamp, a fluorescent bulb, a light emitting diode (LED), a halogen lamp and natural sun light. In other embodiments, the curing process comprises a first curing step employing an artificial light (e.g., so as to provide conversion sufficient for handling), followed by a second curing step initiated by natural sun light.

In the cured state, the encapsulant is in the form of elastic, soft, transparent, mass having one or more of the following characteristics:

1. a Tg (measured by one or more of a differential scanning calorimetry (DSC), Thermo mechanical analysis (TMA) and dynamic mechanical analysis (DMA)) lower than 50° C. In some embodiments, the Tg of the cured encapsulant is lower than 30° C. In other embodiments, the Tg of the cured encapsulant is lower than 15° C. In still other embodiments, the Tg of the cured encapsulant is lower than 0° C.; In still other embodiments, the Tg of the cured encapsulant is lower than −20° C.; In still other embodiments, the Tg of the cured encapsulant is lower than −40° C.; In still other embodiments, the Tg of the cured encapsulant is lower than −50° C.;

2. a light transmission quality similar to EVA and PVB encapsulants. In some embodiments, the light transmission through 500 micrometers (microns) of cured encapsulant according the present invention is at least 90% of original light intensity in the wavelength range of 300 to 800 nanometers. In other embodiments, the light transmission through 500 micrometers of cured encapsulant is at least 92% of original light intensity in the range of 300 to 800 nanometers. In further embodiments, the light transmission through 500 micrometers of cured encapsulant is at least 95% of original light intensity in the range of 300 to 800 nanometers.

The light transmission is retained for long periods outdoors. In several exposure experiments it was shown that a cured encapsulant according the present invention, 500 microns-thick, cured between two glass plates 4 mm thick, exposed outdoors (Israel, the panel was installed on a roof, face up, 20 degrees elevation) for 1 year, retained at least 90% of its original transmission. Similarly, a cured encapsulant according the present invention, 500 microns thick, cured between two glass plates of 4 mm thick, exposed to artificial light (QUV fluorescent bulb weatherometer, UVB 313 bulb, each cycle comprising 8 hours light at black panel temperature of 65-75 C and 4 hours dark, total 1000 hours), retained at least 90% of its original transmission;

3. an elasticity and thus a degree of softness that is crucial for minimizing stress buildup on PV module and delicate wiring during thermal cycling. The cured encapsulant has tensile storage modulus of 0.001 to 250 Megapascals (MPa) at 23° C., measured by Dynamical mechanical analyzer (DMA) at 1 Hz. In some embodiments, the cured encapsulant has tensile storage modulus of 0.05 to 100 MPa at 23° C. In other embodiments, the cured encapsulant has tensile storage modulus of 0.001 to 80 MPa; In further embodiments, the cured encapsulant has tensile storage modulus of 0.5 to 300 MPa at −40° C. In further embodiments, the cured encapsulant has tensile storage modulus of 0.001 to 250 MPa at −40° C.

4. a Shore hardness according ASTM D-2240 ranging from soft gel to 100 A. In some embodiments, the cured encapsulant has shore hardness of 5 to 85 A;

5. a refractive index (RI) of between 1.4 and 1.6. In some other embodiments, the RI is between 1.45 and 1.56; and

6. an adhesion to primed (to a pre-treated surface) or un-primed glass, metal, plastic and PV cell. In some embodiments, the cured encapsulant has peel strength of at least 0.5 Newtons per linear inch (PLI). In other embodiments, the cured encapsulant has adhesion such that a PV module comprising an aluminum back sheet, a silicon PV cell and a 4-mm glass cover, encapsulated by the encapsulant according the present invention, withstands at least 200 thermal cycles from minus 40° C. to +85° C., according to IEC 61215, without delamination and blistering.

As a person skilled in the art would appreciate, the invention provides a simple and low energy consumption manufacturing and molding process of PV modules. Thermoplastic based encapsulants, especially EVA, ionomer and PVB, require two melting steps: first—melt kneading of the polymer, heat stabilizers, adhesion promoters and free radical initiators (usually organic peroxide or azo compound) to obtain homogeneous mixture that is calendared to a sheet; second—the sheet is hot laminated onto the PV module for periods of 15 to 60 minutes at a temperature between 120 and 180° C. These processes are time and energy consuming and thus are cost ineffective and also have negative impact on CO₂ emission.

On the contrary, as explained hereinabove, the formulation of the present invention may be prepared at low temperatures, typically in the range of 20-40° C., as disclosed above, usually without any external heating, to obtain a “syrup”, which may be then pumped easily into the PV module cavity or just applied directly onto the open assembly. The curing is obtained usually within up to one minute when the encapsulated module is exposed to UV and/or visible light.

Despite the vast difference between the formulation of the invention and those of the art, the performance of the encapsulated PV module is at least the same as that of the known EVA and PVB encapsulants. Due to the fact the encapsulant according the present invention has significantly a lower modulus of elasticity than EVA, Ionomer and PVB, the stresses at low temperatures on the PV cell are much lower. This advantage becomes mandatory in thin film cells and other fragile PV cells applications.

In one example, an assembled and edge-sealed module comprising a top glass panel, a PV cell and a metal or polymeric back, a polyisobutylene or butyl seal, as silicone, polyurethane, MS polymer or polysulfide secondary seal and an metal or plastic frame, having an encapsulating and bonding layer comprising the encapsulant according the present invention, provides outstanding reliable performance:

1. Transparency is deteriorated by less than 5% after exposure to accelerated weathering ageing according to ISO 4892-3:2006, (QUV fluorescent bulb weatherometer, UVB 313 bulb, each cycle comprising 8 hours light at black panel temperature of 65-75 C and 4 hours dark, total 1000 hours), 1000 hours;

2. No delamination, discoloration and haze after outdoor exposure providing 60 KW h/m² sun irradiation, according to IEC 61215;

3. No delamination between encapsulant and glass and PV cell after 200 cycles from −40° C. to +85° C., according to IEC 61215; and

4. No delamination, discoloration and haze after 1,000 hours at 85° C. and 85% relative humidity, according to IEC 61215.

There is thus, additionally provided a PV module comprising at least one layer of a cured formulation according to the invention.

In some embodiments, the PV module comprises at least one PV cell and at least one surface selected from glass and polymer films such as fluorine containing polymers and acrylic polymers, wherein bonding between said cell and said at least one surface is provided, e.g., through at least one point of contact, by a bonding layer comprising the encapsulant formulation according to the present invention.

As used herein, a PV module consists of several interconnected PV cells that are embedded or bonded to one or two glass or plastic plates, with a bonding layer comprising a formulation according to the invention. In some embodiments, the bonding layer is the cured film prepared from the formulation of the present invention.

Typically, the PV module has a transparent front side (usually glass), at least one encapsulated PV cell and backside, usually being non-transparent. However, a transparent back side is also possible.

Between the front side (e.g., glass) and the back side, the PV cells (one or more) are placed, encapsulated with the formulation of the present invention. The PV module may comprise any number of PV cells. In some embodiments, the PV module comprises more than one cell. In other embodiments, the PV module comprises at least 54 cells.

The individual PV cells in the module may be any device, semiconductor (of any semiconductor material, being in the form of a single crystal, poly-crystalline or amorphous) or organic or inorganic that provides electrical potential and/or current when irradiated by light, particularly in the range of wavelengths of 200 to 1,200 nanometers. The PV cells are typically interconnected with thin contacts on the upper and bottom side of the, e.g., semiconductor material.

### DETAILED DESCRIPTION OF EMBODIMENTS

Table 1 summarizes numerous formulations according the present invention, as well as several reference formulations.

TABLE 1
formulations according the present invention.

| | Formula | Formula | Formula | Formula | Formula | Formula | Comparative | Comparative | Comparative |
|---|---|---|---|---|---|---|---|---|---|
| | 1 | 2 | 3 | 4 | 5 | 6 | 1 | 2 | 3 |
| EOEOEA | 60 | 30 | 22 | 22 | 60 | 44 | 44 | 0 | 0 |
| THFA | 0 | 30 | 22 | 22 | 0 | 0 | 0 | 0 | 0 |
| Acrylic resin | 34.5 | 34.5 | 34.5 | 34.5 | 0 | 0 | 0 | 34.5 | 34.5 |
| PU-ACR | 0 | 0 | 0 | 0 | 34.5 | 34.5 | 34.5 | 0 | 0 |
| PLAST | 0 | 0 | 16 | 16 | 0 | 16 | 0 | 16 | 16 |
| PHOTO-I | 0.5 | 0.5 | 0.5 | 0.5 | 0.5 | 0.5 | 0.5 | 0.5 | 0.5 |
| Acrylic A | 5 | 5 | 5 | 0 | 5 | 5 | 5 | 5 | 5 |
| ZrOR | 0 | 0 | 0 | 1 | 0 | 0 | 0 | 0 | 0 |
| AR-PLAST | 0 | 0 | 0 | 0 | 0 | 0 | 16 | 0 | 0 |
| IBOA | 0 | 0 | 0 | 0 | 0 | 0 | 0 | 44 | 0 |
| 2PHEA | 0 | 0 | 0 | 0 | 0 | 0 | 0 | 0 | 44 |

EOEOEA-2-(2-ethoxyethoxy)ethyl acrylate (SR256 by Sartomer);
THFA-tetrahydrofurfuryl acrylate (SR285 by Sartomer);
acrylic resin-Elvacite 2044 (manufactured by Lucite);
PU-ACR-an aliphatic polyurethane methacrylate (GENOMER 4256 by Rahn AG);
PLAST-an aliphatic plasticizer Bis[2-(2-butoxyethoxy)ethyl] adipate;
PHOTO-I-a photo initiator (GENOCURE LTM by Rahn AG);
Acrylic A-acrylic acid;
ZrOR-organo zirconate (Ken-React NZ44 manufactured by Kenrich Petrochemicals);
AR-PLAST-an aromatic plasticizer dioctyl phthalate;
IBOA-isobornyl acrylate (SR506D by Sartomer);
2PHEA-2-phenoxy ethyl acrylate (SR339C by Sartomer).

The formulations listed in Table 1, being exemplary formulations according to the invention have been used as disclosed hereinabove.

Each of the formulations (Formulas 1 to 6, as well as the reference formulations listed) were each poured onto a silicon PV cell on both sides and two glass plates, 4 mm-thick each, were assembled one on each of the faces, so as to provide a multilayered structure in the form of: [4 mm glass]-[200-300 microns encapsulant]-[silicon PV cell]-[200-300 microns encapsulant]-[4 mm glass].

The encapsulant was cured from both sides, e.g., through each of the two glass plates by exposure to UV/visible light employing a medium pressure mercury lamp with an intensity of 75 mW/cm² in the 320-390 nm range, for 30 seconds. The panel size was 100×100 mm. The edges were sealed by butyl rubber tape, covered by aluminum foil from its external side.

Each of the nine panels has been formed using a different formulation according to Table 1 and was tested by exposing each to:
1. accelerated weathering ageing according to ISO 4892-3:2006, (QUV fluorescent bulb weatherometer, UVB 313 bulb, each cycle comprising 8 hours light at black panel temperature of 65-75° C. and 4 hours dark) 1000 hours;
2. a 60 KW h/m² outdoor sun irradiation, according to IEC 61215;
3. 200 cycles from −40° C. to +85° C., according to IEC 61215; and
4. 1,000 hours at 85° C. at 85% relative humidity, according to IEC 61215.

The results of these ageing tests are summarized in Table 2. As illustrated, aromatic molecules—either as integral part of the cross-linked matrix (comparative example 3) or as free molecule (comparative example 1), caused severe yellowing and loss of clarity. Such formulations comprising aromatic monomers, oligomers or polymers are therefore not suitable for PV module encapsulation and are thus excluded. On the contrary, acrylic polymers, as well as aliphatic urethane acrylates are suitable for PV module encapsulation.

As the results further indicate, low Tg monomers (namely, monomers providing cross-linked and/or polymerized matrix having a low Tg), such as EOEOEA or THFA, are useful for formulating light curable liquid PV module encapsulants.

However, high Tg monomers (namely, monomers providing cross-linked and/or polymerized matrix having a high Tg and also high elastic modulus), even if aliphatic and having excellent UV and thermal resistance, are not soft enough to retain adhesion under thermal cycling, as evident from comparative example 2.

The aliphatic plasticizers are useful in lowering elastic modulus of light curable liquid PV module encapsulants, enabling better resistance to thermal cycling, with low impact on thermal and photo durability. Similarly, acidic monomers, as well as organo metallic adhesion promoters, are useful in providing primer-less adhesion between the light curable liquid PV module encapsulant of the invention and glass and PV silicon cell.

TABLE 2
summary of accelerated ageing of formulations as disclosed herein.

| | QUV | Outdoor | Thermal | Heat/ |
|---|---|---|---|---|
| Formula | weatherometer | exposure | cycling | humidity |
| 1 | Retention of | Retention of | Retention of | Retention of |
| | clarity and | clarity and | clarity and | clarity and |
| | adhesion | adhesion | adhesion, | adhesion, no |
| | | | very few | blistering |
| | | | delamination | |
| 2 | Retention of | Retention of | Retention of | Retention of |
| | clarity and | clarity and | clarity and | clarity and |
| | adhesion | adhesion | adhesion, few | adhesion, no |
| | | | delamination | blistering |
| 3 | Retention of | Retention of | Retention of | Retention of |
| | clarity and | clarity and | clarity and | clarity and |
| | adhesion | adhesion | adhesion, no | adhesion, no |
| | | | delamination | blistering |
| 4 | Retention of | Retention of | Retention of | Retention of |
| | clarity and | clarity and | clarity and | clarity and |
| | adhesion | adhesion | adhesion, no | adhesion, no |
| | | | delamination | blistering |
| 5 | Retention of | Retention of | Retention of | Retention of |
| | clarity and | clarity and | clarity and | clarity and |
| | adhesion, | adhesion, | adhesion, no | adhesion, no |
| | slight but | slight but | delamination | blistering |
| | negligible | negligible | | |
| | yellowing | yellowing | | |
| 6 | Retention of | Retention of | Retention of | Retention of |
| | clarity and | clarity and | clarity and | clarity and |
| | adhesion, | adhesion, | adhesion, no | adhesion, no |
| | slight but | slight but | delamination | blistering |
| | negligible | negligible | | |
| | yellowing | yellowing | | |
| Compara- | Loss of | Loss of | Retention of | Retention of |
| tive 1 | clarity, | clarity, | clarity and | clarity and |
| | severe | severe | adhesion, | adhesion, no |
| | yellowing | yellowing | yellowing, no | blistering, |
| | | | delamination | yellowing |
| Compara- | Retention of | Retention of | Retention of | Retention of |
| tive 2 | clarity and | clarity and | clarity and | clarity and |
| | adhesion | adhesion | adhesion, | adhesion, |
| | | | heavy | heavy |
| | | | delamination | blistering |
| Compara- | Loss of | Loss of | loss of | loss of |
| tive 3 | clarity, | clarity, | clarity, | clarity, |
| | severe | severe | retention of | retention of |
| | yellowing | yellowing | adhesion, | adhesion, |
| | | | yellowing, | yellowing, |
| | | | slight | slight |
| | | | delamination | blistering |

1.-29. (canceled)

30. A photovoltaic module comprising at least one layer or film of a cured encapsulant, wherein the encapsulant in the uncured liquid state comprises at least one high durability polymer (HDP), at least one unsaturated monomer and/or oligomer, and at least one photoinitiator.

31. The photovoltaic module according to claim 30, comprising at least one photovoltaic cell and at least one surface selected from glass and plastic, wherein bonding between the cell and the at least one surface is provided by a bonding layer comprising the cured encapsulant.

32. The photovoltaic module according claim 30, wherein the photovoltaic cell is selected so as to provide electrical potential and/or current when irradiated by light, in the range of wavelengths of from 200 to 1,200 nanometers.

33. The photovoltaic module according to claim 30, wherein the cured encapsulant has a Tg lower than 50° C., lower than 30° C., lower than 15° C., lower than 0° C., lower than −20° C., lower than −40° C., or lower than −50° C.

34. The photovoltaic module according to claim 30, wherein the cured encapsulant has a light transmission through 500 micrometers (microns) of cured mass of at least 85% of the original light intensity in the wavelength range of from 300 to 800 nanometers.

35. The photovoltaic module according to claim 30, wherein the cured encapsulant has tensile storage modulus at 1 Hz at 23° C. of from 0.001 to 250 MPa or tensile storage modulus at 1 Hz at −40° C. of from 0.001 to 250 MPa.

36. The photovoltaic module according to claim 30, wherein the cured encapsulant has a shore hardness according ASTM D-2240 of soft gel to 100 A.

37. The photovoltaic module according to claim 30, wherein the cured encapsulant has a refractive index of from 1.4 to 1.6.

38. The photovoltaic module according to claim 30, wherein the layer or film has a thickness of from 10 microns to 5 millimeters.

39. A liquid encapsulant formulation for an optical photovoltaic module assembly comprising at least one high durability polymer (HDP), at least one unsaturated monomer and/or oligomer, and at least one photoinitiator, the liquid encapsulant being polymerizable and/or cross-linkable in response to light.

40. The formulation according to claim 39, having a viscosity at the temperature of application in the range of from 5 to 50,000 centipoises (cps) at a shear rate of 10 sec⁻¹.

41. The formulation according to claim 39, wherein the at least one HDP is a linear or branched or cycloaliphatic polymer selected from the group consisting of polyester, polyurethane, acrylic, and methacrylic polymer.

42. The formulation according to claim 39, wherein the at least one HDP has a Tg lower than 50° C., lower than 40° C., lower than 0° C., lower than −20° C., or lower than −40° C.

43. The formulation according to claim 39, wherein the at least one unsaturated monomer or oligomer is an aliphatic or cycloaliphatic or heterocyclic monomer or oligomer.

44. The formulation according to claim 39, wherein the at least one unsaturated oligomer is selected from the group consisting of a urethane acrylate, a polyester acrylate, and an aliphatic unsaturated polyester or any methacrylate derivative thereof.

45. The formulation according to claim 39, further comprising at least one additive selected from the group consisting of a plasticizer; an adhesion promoting agent in the form of a monomer, an oligomer or a polymer; and a stabilizer.

46. The formulation according to claim 39, wherein the at least one photoinitiator is selected so as to initiate polymerization and cross-linking when exposed to UV and/or visible light.

47. The formulation according to claim 39, wherein the at least one photoinitiator is selected from the group consisting of 2-hydroxy-2-methyl-1-phenyl-propan-1-one; 2,4,6-trimethylbenzoyl-diphenyl-phosphineoxide; 1-hydroxy-cyclohexyl-phenyl-ketone; bis(2,6-dimethoxy benzoyl)-2,4,4-trimethyl-pentylphosphine oxide; 1-[4-(2-hydroxyethoxy)-phenyl]-2-hydroxy-2-methyl-1-propane-1-one; 2,2-dimethoxy-1,2-diphenylethan-1-one; and 2-methyl-1[4-(methylthio)phenyl]-2-morpholinopropan-1-one.

48. A cured encapsulant mass prepared by providing a formulation according to claim 37, and curing the formulation.

49. A device capable of providing electrical potential and/or current when irradiated by light, in the range of wavelengths of from 200 to 1,200 nanometers, comprising at least one layer or film of a cured encapsulant, wherein the encapsulant in the uncured liquid state comprises at least one high durability polymer (HDP), at least one unsaturated monomer and/or oligomer, and at least one photoinitiator.
